(19) United States
(12) Patent Application Publication
(10) Pub. No.: US 2013/0304413 A1
(43) Pub. Date: Nov. 14, 2013

(54) COMPUTING DEVICE AND METHOD FOR TESTING ELECTROMAGNETIC COMPATIBLITY OF PRINTED CIRCUIT BOARD

(71) Applicants: HONG FU JIN PRECISION INDUSTRY (SHENZHEN) CO., LTD., Shenzhen (CN); HON HAI PRECISION INDUSTRY CO., LTD., New Taipei (TW)

(72) Inventor: GUANG-FENG OU, Shenzhen (CN)

(73) Assignees: HON HAI PRECISION INDUSTRY CO., LTD., New Taipei (TW); HONG FU JINPRECISION INDUSTRY (ShenZhen) CO., LTD., Shenzhen (CN)

(21) Appl. No.: 13/758,005

(22) Filed: Feb. 4, 2013

(30) Foreign Application Priority Data
May 10, 2012 (CN) 201210143477.6

(51) Int. Cl. G01R 31/28; G06F 17/00

(52) U.S. Cl. CPC G01R 31/2834; G06F 17/00
USPC 702/119

(57) ABSTRACT

An electromagnetic compatibility (EMC) testing system includes a layout information obtaining module, a script loading module, a script executing module, and a report generating module. The layout information obtaining module obtains layout information of a printed circuit board. The script loading module loads an EMC testing script which includes EMC rules. The script executing module executes the EMC testing script to determine whether the layout information of the printed circuit board complies with the EMC rules. The report generating module generates an EMC report describing whether the layout information of the printed circuit board complies with the EMC rules.

### REFERENCE TO RELATED APPLICATIONS

This application claims all benefits accruing under 35 U.S.C. §119 from China Patent Application No. 201210143477.6, filed on May 10, 2012 in the State Intellectual Property Office of China. The contents of the China Application are hereby incorporated by reference.

### BACKGROUND

1. Technical Field

The disclosure generally relates to a field of electromagnetic compatibility (EMC) test, and particularly relates to a computing device and method for testing EMC of a printed circuit board.

2. Description of Related Art

A printed circuit board mechanically supports and electrically connects electronic components using conductive signal traces etched from copper sheets laminated onto a non-conductive substrate. The printed circuit board often has massive signal traces which may cause electromagnetic interference (EMI). Thus, the design of the layout of the printed circuit board is required to comply with EMC rules. However, the existing EMC testing technology depends very much on human experiences and judgments, which results in low accuracy and low efficiency.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the views.

FIG. 1 is a block diagram of one embodiment of a computing device suitable for employing an EMC testing system.

FIG. 2 is a block diagram of one embodiment of the EMC testing system of FIG. 1.

FIG. 3 is a flowchart showing one embodiment of an EMC testing method.

### DETAILED DESCRIPTION

The disclosure is illustrated by way of example and not by way of limitation in the figures of the accompanying drawings, in which like reference numerals indicate similar elements. It should be noted that references to “an” or “one” embodiment in this disclosure are not necessarily to the same embodiment, and such references can mean “at least one.”

In general, the word “module,” as used herein, refers to logic embodied in hardware or firmware, or to a collection of software instructions, written in a programming language such as Java, C, or assembly. One or more software instructions in the modules may be embedded in firmware, such as in an erasable-programmable read-only memory (EPROM). The modules described herein may be implemented as either software and/or hardware modules and may be stored in any type of non-transitory computer-readable medium or other storage device. Some non-limiting examples of non-transitory computer-readable media are compact discs (CDs), digital versatile discs (DVDs), Blu-Ray discs, Flash memory, and hard disk drives.

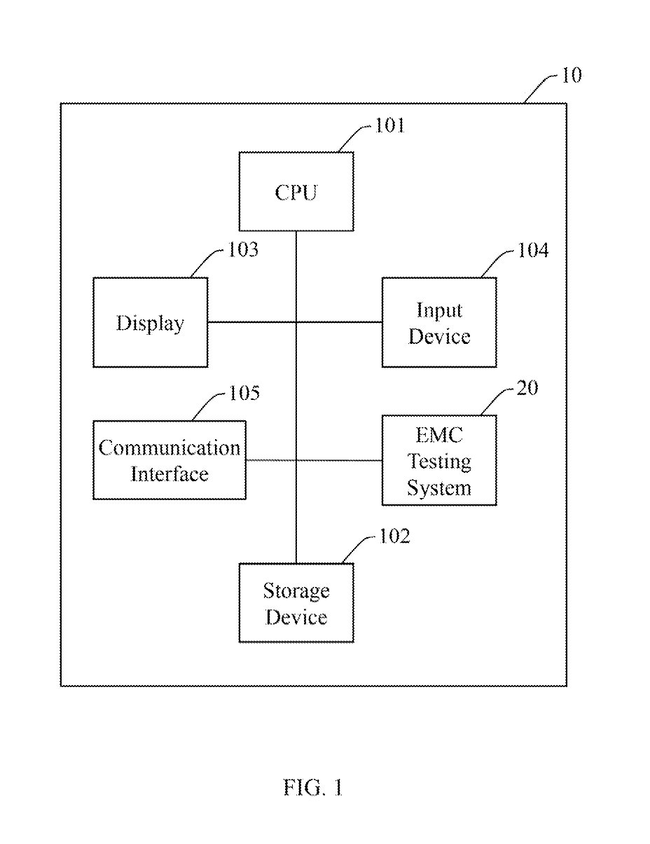

FIG. 1 shows one embodiment of a computing device 10. The computing device 10 includes a central processing unit (CPU) 101, a storage device 102, a display 103, an input device 104 and a communication interface 105. The computing device 10 may be a host computer, a workstation computer, a server computer, a tablet computer, or the like. An EMC testing system 20 may be employed in the computing device 10 and executable by the computing device 10, and is configured for testing EMC of a printed circuit board.

The CPU 101 is operably coupled to the storage device 102, the display 103, and the input device 104. The CPU 101 may include one or more processors that provide the processing capability to execute the operating system, programs, user and application interfaces, and any other functions of the computing device 10. The CPU 101 may include one or more microprocessors and/or related chip sets. For example, the CPU 101 may include “general purpose” microprocessors, a combination of general and special purpose microprocessors, instruction set processors, graphics processors, video processors, related chips sets, and/or special purpose microprocessors. The CPU 101 also may include onboard memory for caching purposes.

Information, such as programs and/or instructions, used by the CPU 101 may be located within the storage device 102. The storage device 102 may store a variety of information and may be used for various purposes. For example, the storage device 102 may store firmware for the computing device 10 (such as a basic input/output instruction or operating system instructions), various programs, applications, or routines executed on the computing device 10, user interface functions, processor functions, and so forth. In addition, the storage device 102 may be used for buffering or caching during operation of the computing device 10.

The storage device 102 may include any suitable manufacture that includes one or more tangible, computer-readable media. For example, the storage device 102 may include a volatile memory, such as random access memory (RAM), and/or as a non-volatile memory, such as read-only memory (ROM). The components may further include other forms of computer-readable media, such as non-volatile storage, for persistent storage of data and/or instructions. The non-volatile storage may include flash memory, a hard drive, or any other optical, magnetic, and/or solid-state storage media. The non-volatile storage may be used to store firmware, data files, software, wireless connection information, and any other suitable data.

The display 103 may provide a visual output interface between the computing device 10 and a user. The visual output may include text, graphics, video, and any combination thereof. The display 103 may use LCD (liquid crystal display) technology, or LPD (light emitting polymer display) technology, although other display technologies may be used in other embodiments. In some embodiments, the display 103 may be a touch-sensitive display which also accepts input from the user based on haptic and/or tactile contact through a touch-sensitive surface.

The input device 104 may provide an input interface between the computing device 10 and a user. The input device 104 may be a keyboard, a mouse or a touch pad, which can be used to input information.

The communication interface 105 may provide connectivity channels for receiving and transmitting information and/or for connecting to other computing devices.

The communication interface 105 may represent, for example, a network interface card (NIC) or a network controller. The communication interface 105 may include a local area network (LAN) interface for connecting to a wired Ethernet-based network and/or a wireless LAN, such as an IEEE 802.11x wireless network. The communication interface 105 also may include a wide area network (WAN) interface that permits connection to the Internet.

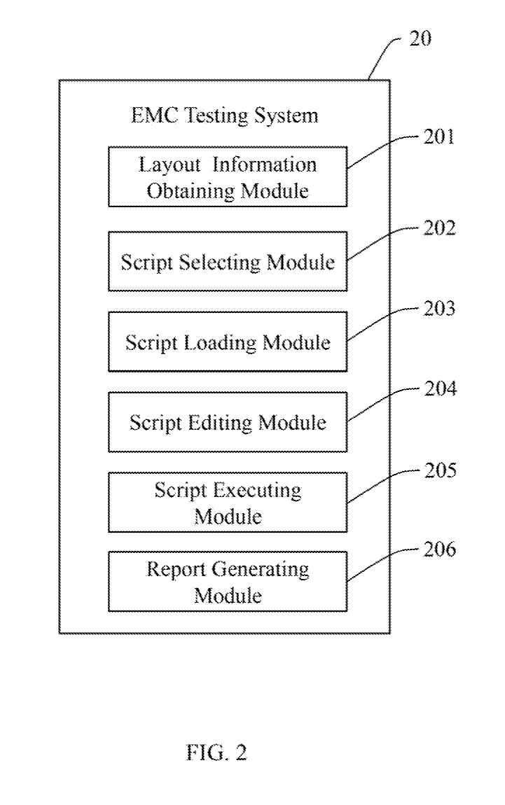

FIG. 2 shows a functional block diagram of one embodiment of the EMC testing system 20. The EMC testing system 20 includes a layout information obtaining module 201, a script selecting module 202, a script loading module 203, a script editing module 204, a script executing module 205, and a report generating module 206.

The layout information obtaining module 201 may obtain layout information of a printed circuit board. The layout information may include trace names, trace widths and trace positions of traces of the layout pattern of the printed circuit board.

The script selecting module 202 may retrieve one or more EMC testing scripts from a script library, which may be stored in the local storage device 102 or in a remote computer accessible through the communication interface 105. The script selecting module 202 may display the one or more EMC testing scripts in the display 103 and allow a user to select one of them. Each EMC testing script includes a plurality of EMC rules, which pertain to and follow certain EMC standards. Each EMC rule may define a requirement of a parameter of the printed circuit board layout, such as requiring a width of a power supply trace to be between 10 to 15 mils.

The script loading module 203 may load the selected EMC testing script and put the EMC rules of the selected EMC testing script in a queue.

The script editing module 204 may provide a user interface to display the EMC rules of the selected EMC testing script and allow a user to edit the EMC rules through the user interface. The user may add a new EMC rule into the EMC testing script, delete an EMC rule from the EMC testing script, or modify one of the EMC rules of the EMC testing script.

In some embodiments, each of the EMC rules is associated with an expiration date. The script editing module 204 may decide whether each of the EMC rules is expired. When one of the EMC rules is expired, the script editing module 204 may remove the one of the EMC rules from the EMC testing script.

The script executing module 205 may execute the selected EMC testing script to determine whether the layout information of the printed circuit board complies with the EMC rules of the selected EMC testing script.

The report generating module 206 may generate an EMC report depicting whether the layout information of the printed circuit board complies with the EMC rules of the selected EMC testing script.

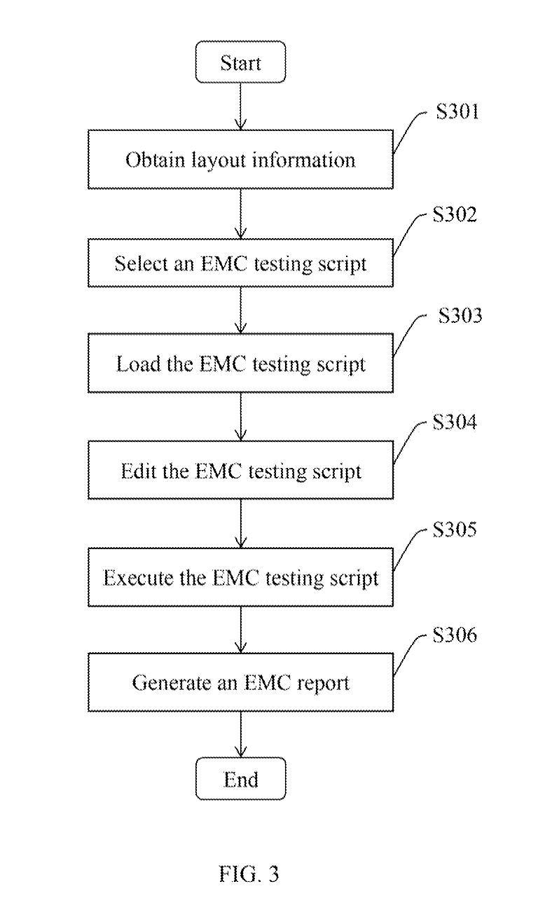

FIG. 3 is a flowchart showing one embodiment of a method for testing EMC of a printed circuit board. The method comprises the following steps.

In step S301, the layout information obtaining module 201 obtains layout information of a printed circuit board. The layout information may include trace names, trace widths and trace positions of traces of the layout pattern of the printed circuit board.

In step S302, the script selecting module 202 retrieves one or more EMC testing scripts from a script library and displays the one or more EMC testing scripts in the display 103 and allows a user to select one of them.

In step S303, the script loading module 203 loads the selected EMC testing script and puts the EMC rules of the selected EMC testing script in a queue.

In step S304, the script editing module 204 provides a user interface to display the EMC rules of the selected EMC testing script and allows a user to edit the EMC rules through the user interface.

In step S305, the script executing module 205 executes the selected EMC testing script to determine whether the layout information of the printed circuit board in fact complies with the EMC rules of the selected EMC testing script.

In step S306, the report generating module 206 generates an EMC report depicting whether the layout information of the printed circuit board complies with the EMC rules of the selected EMC testing script.

In some embodiments, each of the EMC rules is associated with an expiration date. The method further includes the step of the script editing module 204 determining whether any of the EMC rules is expired. When one of the EMC rules is expired, the script editing module 204 removes the expired EMC rule from the EMC testing script.

Although numerous characteristics and advantages have been set forth in the foregoing description of embodiments, together with details of the structures and functions of the embodiments, the disclosure is illustrative only, and changes may be made in detail, especially in the matters of arrangement of parts within the principles of the disclosure to the full extent indicated by the broad general meaning of the terms in which the appended claims are expressed.

In particular, depending on the embodiment, certain steps or methods described may be removed, others may be added, and the sequence of steps may be altered. The description and the claims drawn for or in relation to a method may give some indication in reference to certain steps. However, any indication given is only to be viewed for identification purposes, and is not necessarily a suggestion as to an order for the steps.

What is claimed is:

1. A computing device for testing electromagnetic compatibility (EMC) of a printed circuit board, the computer device comprising:
a storage device;
at least one processor coupled to the storage device; and
one or more programs stored in the storage device and executed by the at least one processor, the one or more programs comprising:
a layout information obtaining module configured to obtain layout information of the printed circuit board;
a script loading module configured to load an EMC testing script, the EMC testing script comprising a plurality of EMC rules;
a script executing module configured to execute the EMC testing script to determine whether the layout information of the printed circuit board complies with the plurality of EMC rules; and
a report generating module configured to generate an EMC report depicting whether the layout information of the printed circuit board complies with the plurality of EMC rules.

2. The computing device of claim 1, wherein each of the plurality of EMC rules is associated with an expiration date.

3. The computing device of claim 2, further comprising a script editing module configured to decide whether an EMC rule of the plurality of EMC rules has passed the expiration date, and to remove the EMC rule from the EMC testing script if the EMC rule has passed the expiration date.

4. The computing device of claim 3, wherein the script editing module is further configured to provide a user interface to display the plurality of EMC rules and allow a user to edit the plurality of EMC rules through the user interface.

5. The computing device of claim 4, wherein the script editing module is further configured to allow the user to add new EMC rules to the EMC testing script.

6. The computing device of claim 4, wherein the script editing module is further configured to allow the user to modify the plurality of EMC rules.

7. The computing device of claim 1, further comprising a selecting module configured to select the EMC testing script from a script library.

8. A method for testing electromagnetic compatibility (EMC) of a printed circuit board, the method comprising:
obtaining layout information of the printed circuit board;
loading an EMC testing script, the EMC testing script comprising a plurality of EMC rules;
executing the EMC testing script to determine whether the layout of the printed circuit board complies with the plurality of EMC rules; and
generating an EMC report depicting whether the layout of the printed circuit board complies with the plurality of EMC rules.

9. The method of claim 8, further comprising:
associating each of the plurality of EMC rules with an expiration date.

10. The method of claim 9, further comprising:
deciding whether each of the plurality of EMC rules has passed the expiration date; and
when an EMC rule of the plurality of EMC rules has passed the expiration date, removing the EMC rule from the EMC testing script.

11. The method of claim 8, further comprising:
selecting the EMC testing script from a script library.

12. The method of claim 8, further comprising:
providing a user interface to display the plurality of EMC rules; and
editing the plurality of EMC rules through the user interface.

13. The method of claim 12, wherein the editing comprises:
adding new EMC rules to the EMC testing script.

14. The method of claim 12, wherein the editing comprises:
modifying the plurality of EMC rules.

15. A non-transitory computer-readable storage medium having stored thereon instructions that, when executed by at least one processor of a computing device, cause the computing device to perform a method for testing electromagnetic compatibility (EMC) of a printed circuit board, the method comprising:
obtaining layout information of the printed circuit board;
loading an EMC testing script, the EMC testing script comprising a plurality of EMC rules;
executing the EMC testing script to determine whether the layout of the printed circuit board complies with the plurality of EMC rules; and
generating an EMC report depicting whether the layout of the printed circuit board complies with the plurality of EMC rules.

16. The storage medium of claim 15, wherein the method further comprises:
associating each of the plurality of EMC rules with an expiration date.

17. The storage medium of claim 16, wherein the method further comprises:
deciding whether each of the plurality of EMC rules has passed the expiration date; and
when an EMC rule of the plurality of EMC rules has passed the expiration date, removing the EMC rule from the EMC testing script.

18. The storage medium of claim 15, wherein the method further comprises:
selecting the EMC testing script from a script library.

19. The storage medium of claim 15, wherein the method further comprises:
providing a user interface to display the plurality of EMC rules; and
editing the plurality of EMC rules through the user interface.

20. The storage medium of claim 19, wherein the editing comprises:
adding new EMC rules to the EMC testing script.
